(19) United States
(12) Patent Application Publication
(10) Pub. No.: US 2012/0168956 A1
(43) Pub. Date: Jul. 5, 2012

(54) CONTROLLING DENSITY OF PARTICLES WITHIN UNDERFILL SURROUNDING SOLDER BUMP CONTACTS

(75) Inventors: Stephane S. Barbeau, Shefford (CA); Catherine C. Dufort, Bromont (CA); Ian D. Melville, Highland, NY (US); Luc L. Ouellet, Bromont (CA); Marie-Claude Paquet, Bromont (CA); Wolfgang Sauter, Hinesburg, VT (US); Jeffrey S. Zimmerman, Swanton, VT (US)

(73) Assignee: International Business Machines Corporation, Armonk, NY (US)

(21) Appl. No.: 12/984,069

(22) Filed: Jan. 4, 2011

(51) Int. Cl. H01L 23/48; H01L 21/50

(52) U.S. Cl. 257/773; 438/127; 257/E23.01; 257/E21.499

(57) ABSTRACT

A method forms an integrated circuit structure, using a manufacturing device, to have kerf regions and external contacts, and to have conductive structures in the kerf regions. The method also forms an underfill material on a surface of the integrated circuit structure, using the manufacturing device, that contacts the kerf regions and the external contacts. The underfill material comprises electrically attracted filler particles that affect the coefficient of thermal expansion and elastic modulus of the underfill material. When forming the underfill material, the method applies an electrical charge to the conductive structures and the external contacts.

### BACKGROUND

The present invention relates to integrated circuit devices, and more specifically, to the underfill material that is utilized to bond the integrated circuit devices to the laminate substrate, and to controlling the density of particles within the underfill material using electrical charge.

When manufacturing integrated circuit devices (which are sometimes referred to as integrated circuit chips once a wafer of such devices is divided into different sections) automated machinery is used to form layers of integrated circuit components, such as transistors, capacitors, resistors, wiring, etc., that make up the integrated circuit device. Then, the integrated circuit components are assembled onto a laminate substrate which acts as a mechanical and electrical interface between the integrated circuit chip and the printed circuit board (motherboard).

Solder bumps are typically used as the electrical contacts between the laminate substrate and the integrated circuit device chip. In order to ensure reliable solder ball interconnects, an epoxy underfill material is dispensed between the integrated circuit chip and the laminate substrate.

Underfill adhesion is an important packaging issue. There are several known failure modes that are triggered by loss of adhesion of the underfill material to the chip surface. Underfill delamination from the chip corner surface is a common failure mechanism in flip chip reliability.

### SUMMARY

An exemplary method herein forms an integrated circuit structure connected to a laminate structure, using a manufacturing device. The integrated circuit structure has kerf regions and external contacts, and conductive structures in the kerf regions. The kerf regions define areas of division where the integrated circuit structure will be divided into integrated circuit chips.

The method forms an underfill material between the integrated circuit structure and the laminate structure, using the manufacturing device. The underfill material contacts the kerf regions and the external contacts. The underfill bonds the integrated circuit structure to the laminate substrate.

The underfill material comprises electrically attracted filler particles that affect the coefficient of thermal expansion and elastic modulus of the underfill material. When forming the underfill material, the method applies an electrical charge (approximately 100V, 500V, 1000V, 2000V, etc.) to the conductive structures and/or the external contacts. The electrical charge adjusts the coefficient of thermal expansion of the underfill material in regions of the underfill material that are adjacent to the external contacts and the kerf regions by attracting or repelling the filler particles to or away from the external contacts and the kerf regions.

An integrated circuit structure herein comprises an integrated circuit device (transistors, resistors, etc.) having kerf regions, and a laminate substrate. The kerf regions define where the wafer will be divided into integrated circuit chips. External contacts are positioned on an external surface of the laminate substrate, and the external contacts are electrically connected to the integrated circuit devices. Also, conductive structures are positioned within the kerf regions. An underfill material is dispensed between the integrated circuit device and the laminate substrate. The underfill material contacts the kerf regions and the external contacts.

As mentioned above, the underfill material comprises electrically attracted filler particles that affect the coefficient of thermal expansion and elastic modulus of the underfill material. The density of the filler particles within the underfill material is higher in areas around the kerf regions and the external contacts, relative to other regions of the underfill material. Further, the density of the filler particles makes the coefficient of thermal expansion and elastic modulus of the underfill material uniform in the areas around the kerf regions and the external contacts, relative to the other regions of the underfill material.

### BRIEF DESCRIPTION OF THE SEVERAL VIEWS OF THE DRAWINGS

FIG. 1 is a schematic cross-sectional diagram illustrating an exemplary structure according to embodiments herein;

FIG. 2 is a schematic cross-sectional diagram illustrating an exemplary structure according to embodiments herein;

FIG. 3 is a schematic cross-sectional diagram illustrating an exemplary structure according to embodiments herein;

FIG. 4 is a schematic cross-sectional diagram illustrating an exemplary structure according to embodiments herein;

FIG. 5 is a schematic cross-sectional diagram illustrating an exemplary structure according to embodiments herein;

FIG. 6 is a schematic cross-sectional diagram illustrating an exemplary structure according to embodiments herein; and

FIG. 7 is a schematic cross-sectional diagram illustrating an exemplary structure according to embodiments herein.

### DETAILED DESCRIPTION

As mentioned above, underfill delamination from the integrated circuit chip corner surface is a common failure mechanism in flip chip reliability. A commonly used underfill is an epoxy resin with fairly high coefficient of thermal expansion. One issue that arises is the difference between the coefficient of thermal expansion of the integrated circuit chip structure and the coefficient of thermal expansion of the underfill material. A large difference between these coefficients of thermal expansion could contribute to delamination issues.

In order to address these concerns, embodiments herein include filler particles within the underfill material. The filler particles utilized by embodiments herein have a lower coefficient of thermal expansion than the standard epoxy resins, and therefore reduce the underfill coefficient of thermal expansion (and increase the elastic modulus). During the underfill process, the filler particles are free to move within the epoxy resin. Their final location within the underfill material can create areas of high and low thermal expansion.

So as to control the areas of high and low thermal expansion, the embodiments herein apply an electric field before or during the formation of the underfill material to attract or repel the filler particles. Therefore, by electrically biasing certain areas of a chip prior to and/or during the underfill process, the embodiments herein provide control over the location and amount of filler particle loading. This allows active control over the mechanical properties of the underfill material in areas where it is most critical, such as at the chip corners.

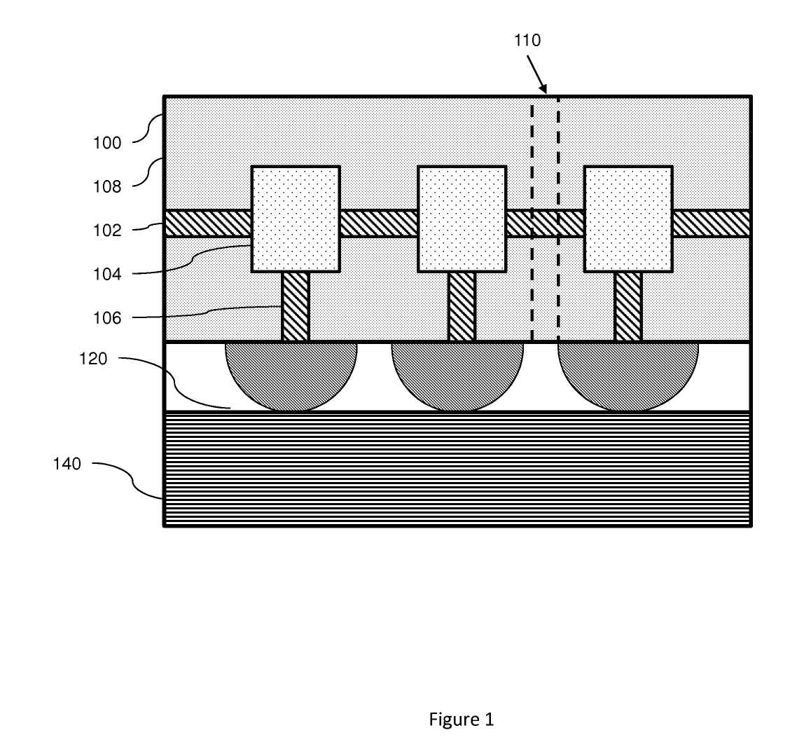

An exemplary method herein is shown in cross-sectional view in FIGS. 1-7. As shown in FIG. 1, a very generalized integrated circuit structure 100 includes a chip substrate 108 and any form of solid-state (integrated circuit) components 104 (transistors, resistors, capacitors, controllers, memory, power units, wiring, etc.) formed within the chip substrate 108. In addition, internal wiring 102 can connect components 104 within the chip substrate 108 and internal wiring 106 can connect the components 104 to external contacts (such as lead-free or lead based solder bumps) 120.

Generally, transistor structures are formed by depositing or implanting impurities into a chip substrate to form at least one semiconductor channel region, bordered by shallow trench isolation regions below the top (upper) surface of the substrate. A chip “substrate” herein can comprise any material appropriate for the given purpose (whether now known or developed in the future) and can comprise, for example, Si, SiC, SiGe, SiGeC, Ge alloys, GaAs, InAs, TnP, other III-V or II-VI compound semiconductors, or organic semiconductor structures, etc. The “shallow trench isolation” (STI) structures are well-known to those ordinarily skilled in the art and are generally formed by patterning openings/trenches within the substrate and growing or filling the openings with a highly insulating material (this allows different active areas of the substrate to be electrically isolated from one another).

For purposes herein, a “semiconductor” is a material or structure that may include an implanted impurity that allows the material to sometimes be a conductor and sometimes be an insulator, based on electron and hole carrier concentration. As used herein, “implantation processes” can take any appropriate form (whether now known or developed in the future) and can comprise, for example, ion implantation, etc.

For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon dioxide silicon nitride, silicon oxynitride, a gate dielectric stack of SiO₂ and Si₃N₄, and metal oxides like tantalum oxide. The thickness of dielectrics herein may vary contingent upon the required device performance. The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as copper, tungsten, hafnium, tantalum, molybdenum, titanium, or nickel, or a metal silicide, any alloys of such metals, and may be deposited using physical vapor deposition, chemical vapor deposition, or any other technique known in the art.

Within a transistor, the semiconductor (or channel region) is positioned between a conductive “source” region and a similarly conductive “drain” region and when the semiconductor is in a conductive state, the semiconductor allows electrical current to flow between the source and drain. A “gate” is a conductive element that is electrically separated from the semiconductor by a “gate oxide” (which is an insulator) and current/voltage within the gate changes the conductivity of the channel region of the transistor.

When patterning any material herein, the material to be patterned can be grown or deposited in any known manner and a patterning layer (such as an organic photoresist) can be formed over the material. The patterning layer (resist) can be exposed to some form of light radiation (e.g., patterned exposure, laser exposure, etc.) provided in a light exposure pattern, and then the resist is developed using a chemical agent. This process changes the characteristic of the portion of the resist that was exposed to the light. Then one portion of the resist can be rinsed off, leaving the other portion of the resist to protect the material to be patterned. A material removal process is then performed (e.g., plasma etching, etc.) to remove the unprotected portions of the material to be patterned. The resist is subsequently removed to leave the underlying material patterned according to the light exposure pattern.

The embodiments herein form the integrated circuit structure 100, using a manufacturing device, to have kerf regions 110 and external contacts 120, and to have conductive structures 112 in the kerf regions 110. The kerf regions 110 define areas of division where the integrated circuit structure 100 will be divided into integrated circuit chips 142 (see FIG. 7, discussed below).

As also shown in FIG. 1, chips 100 with controlled collapse chip connection (C4) solder balls 120 get placed on a laminated 140 such that the C4 solder balls 120 line up with receiving pads on the laminate 140. The chip 100 and laminate 140 go through a reflow furnace that melts the solder 120 and forms the electrical and mechanical connection between chip 100 and laminate 140.

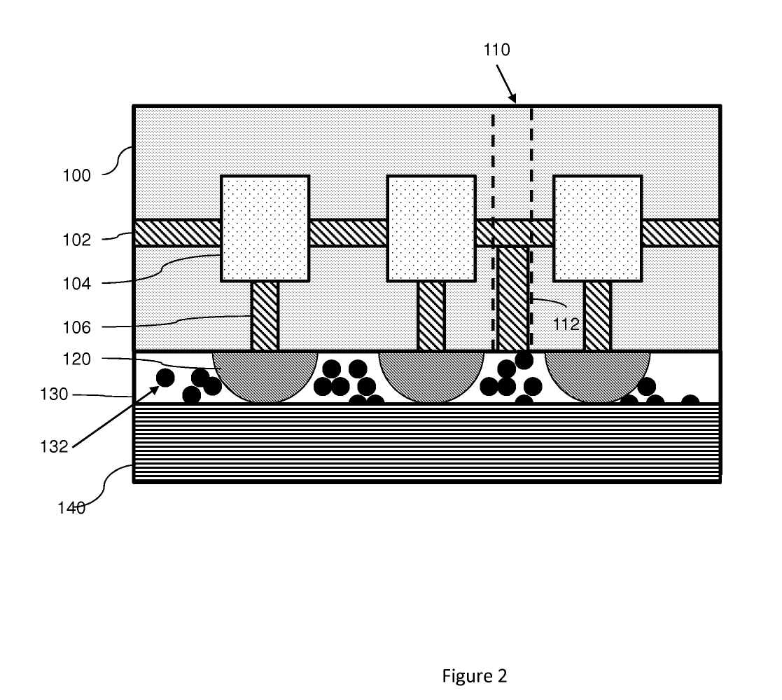

As shown in FIG. 2, an underfill 130 is dispensed along the edge of the chip 100. Through capillary action, the underfill 130 flows into the gap between the chip 100 and laminate 140. The underfill material 130 contacts the kerf regions 110 and the external contacts 120. The underfill material 130 bonds the integrated circuit structure 100 to the laminated structure 140. The underfill material 130 comprises electrically attracted filler particles 132 (made of, for example, silica) that affect the coefficient of thermal expansion and elastic modulus of the underfill material 130.

When dispensing and curing the underfill material 130, the method applies any appropriate positive or negative electrical charge (e.g., approximately +/−100V, 500V, 1000V, 2000V, etc.) to the conductive structures 112 and the external contacts 120. The electrical charge adjusts the coefficient of thermal expansion of the underfill material 130 in regions of the underfill material 130 that are adjacent the external contacts 120 and the kerf regions 110 by attracting or repelling the filler particles 132 to or away from the external contacts 120 and the kerf regions 110.

The electrical charge can be applied before or during the dispense and cure of the underfill material 130, depending upon how well the external contacts 120 and the conductive structures 112 maintain the electrical charge.

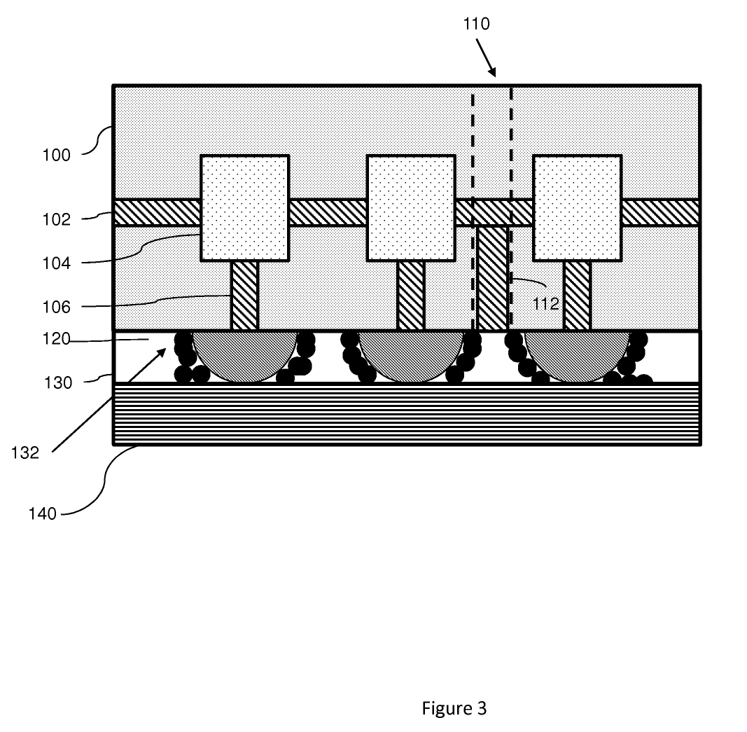

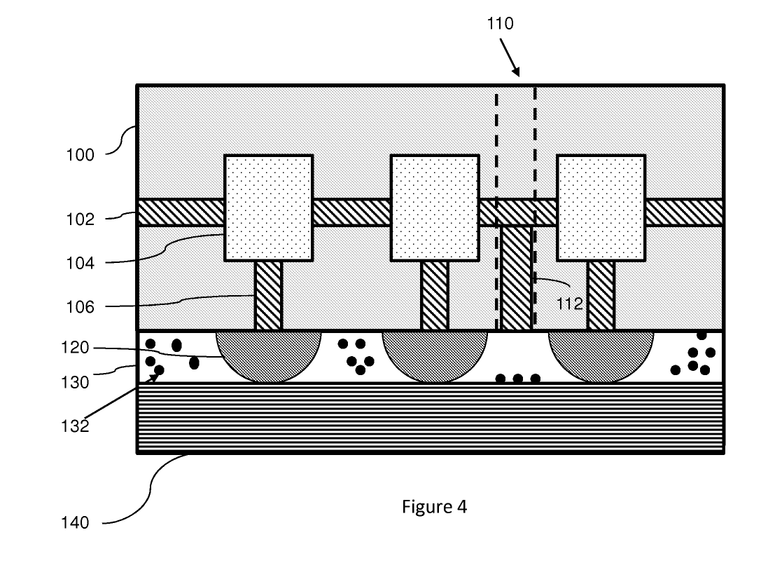

More specifically, FIG. 3 illustrates a situation where the electrical charge attracts the filler particles 132 toward the external contacts 120 and the conductive structures 112. To the contrary, FIG. 4 illustrates a situation where the electrical charge repels the filler particles 132 away from the external contacts 120 and the conductive structures 112.

As would be understood by those ordinarily skilled in the art, the polarity and strength of the electrical charge is coordinated with the polarity and attractive force associated with the filler particles 132 to achieve whatever design goal an individual structure may require. Therefore, while some structures may benefit from many filler particles 132 being attracted to the external contacts 120 and kerf regions 110 (FIG. 3) other structures may benefit from an opposite structure (FIG. 4) while other structures may benefit from an evenly distributed filler particle concentration 132 (FIG. 2) each of which can be controlled according to the electrical charge applied.

Thus, with embodiments herein the density of the filler particles 132 within the underfill material 130 can be higher (or lower) in areas around the kerf regions 110 and the external contacts 120, relative to other regions of the underfill material 130. Further, the density of the filler particles 132 makes the coefficient of thermal expansion and elastic modulus of the underfill material 130 uniform in the areas around the kerf regions 110 and the external contacts 120, relative to the other regions of the underfill material 130.

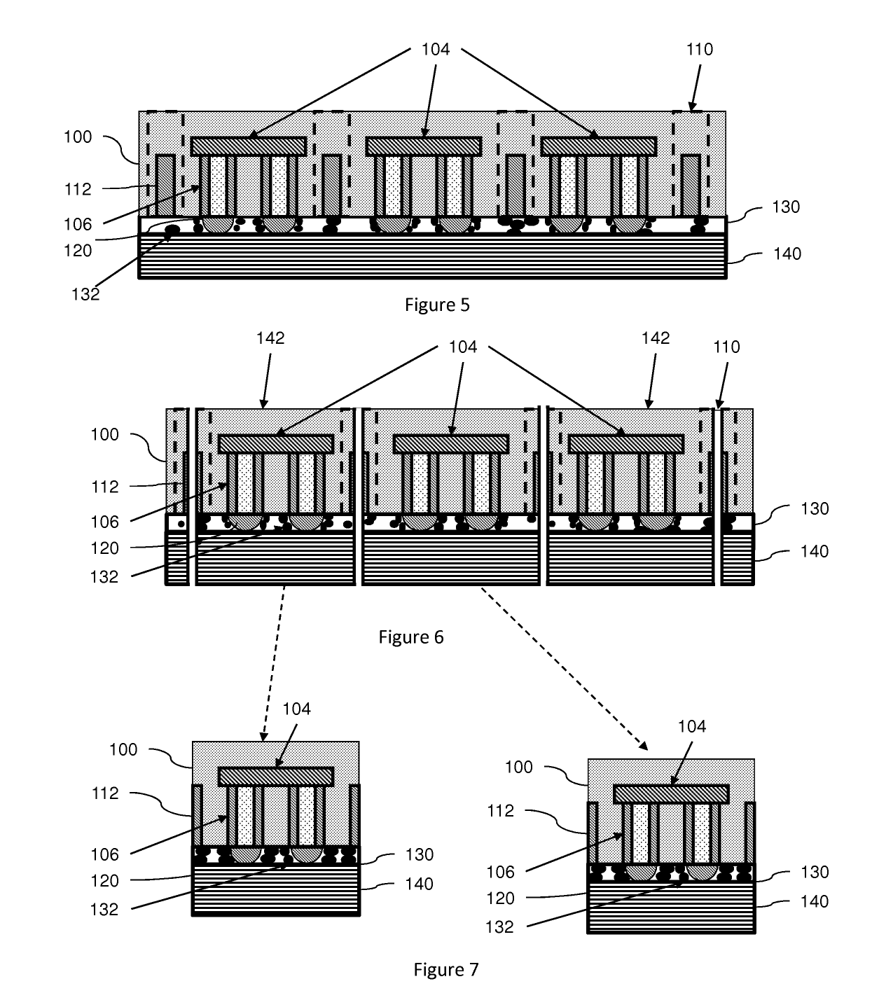

As shown in FIG. 5, during the process of dispensing and curing the underfill material 130, the electrical charge controls the location of the filler particles 132. FIG. 6 illustrates the results of a dicing operation where openings are formed along the kerf region 110 to separate the integrated circuit structure 110 into individual integrated circuit chips 142. As shown in FIG. 7, each individual integrated circuit chip 142 will include a unique arrangement of filler particles 132 (potentially gathered around (or repelled from) the contacts 120 and conductive structures 112). Further, each integrated circuit chip will include at least a portion of the conductive structures 112 positioned along the edges of the integrated circuit chips 142.

As mentioned above, because the embodiments herein control the elastic modulus and coefficient of thermal expansion of the underfill material 130, the underfill material 130 can be made to more closely match the coefficient of thermal expansion of the integrated circuit structure 100. By matching the coefficient of thermal expansion (especially near the edges of the integrated circuit chips 142 (by operation of the conductive structures 112) the chances of delamination are dramatically reduced. Therefore, the embodiments herein increase yield without increasing size, cost, etc.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
forming an integrated circuit structure connected to a laminate structure, using a manufacturing device, said integrated circuit structure having kerf regions and external contacts, and conductive structures in said kerf regions; and
forming an underfill material between said integrated circuit structure and said laminate structure, using said manufacturing device, that contacts said kerf regions and said external contacts,
during said forming of said underfill material, applying an electrical charge to said conductive structures and said external contacts.

2. The method according to claim 1, said electrical charge adjusting a coefficient of thermal expansion of said underfill material in the regions of said underfill material that are adjacent said external contacts and said kerf regions.

3. The method according to claim 1, said electrical charge comprising approximately 1000V.

4. The method according to claim 1, said underfill bonding said integrated circuit structure to said laminated structure.

5. The method according to claim 1, said kerf regions defining integrated circuit chips of said integrated circuit structure.

6. A method comprising:
forming an integrated circuit structure connected to a laminate structure, using a manufacturing device, said integrated circuit structure having kerf regions and external contacts, and conductive structures in said kerf regions; and
forming an underfill material between said integrated circuit structure and said laminate structure, using said manufacturing device, that contacts said kerf regions and said external contacts,
said underfill material comprising electrically attracted filler particles that affect a coefficient of thermal expansion and an elastic modulus of said underfill material, and
during said forming of said underfill material, applying an electrical charge to said conductive structures and said external contacts.

7. The method according to claim 6, said electrical charge adjusting said coefficient of thermal expansion of said underfill material in regions of said underfill material that are adjacent said external contacts and said kerf regions by attracting or repelling said filler particles to or away from said external contacts and said kerf regions.

8. The method according to claim 6, said electrical charge comprising approximately 1000V.

9. The method according to claim 6, said underfill bonding said integrated circuit structure to said laminated structure.

10. The method according to claim 6, said kerf regions defining integrated circuit chips of said integrated circuit structure.

11. An integrated circuit structure comprising:
a substrate having kerf regions;
integrated circuit devices located within and on said substrate;
external contacts positioned on an external surface of said substrate, said external contacts being electrically connected to said integrated circuit devices;
conductive structures in said kerf regions; and
an underfill material on said external surface of said integrated circuit structure, said underfill material contacting said kerf regions and said external contacts,
said underfill material comprising electrically attracted filler particles that affect a coefficient of thermal expansion of said underfill material, and
a density of said filler particles within said underfill material being higher in areas around said kerf regions and said external contacts, relative to other regions of said underfill material.

12. The integrated circuit structure according to claim 11, said density of said filler particles making said coefficient of thermal expansion of said underfill material uniform in said areas around said kerf regions and said external contacts, relative to said other regions of said underfill material.

13. The integrated circuit structure according to claim 11, said filler particles affecting an elastic modulus of said underfill material.

14. The integrated circuit structure according to claim 11, further comprising a laminated structure attached to said external surface of said integrated circuit structure by said underfill material.

15. The integrated circuit structure according to claim 11, said kerf regions defining integrated circuit chips of said integrated circuit structure.

16. An integrated circuit chip comprising:
a substrate having edge regions;
integrated circuit devices located within and on said substrate;
external contacts positioned on an external surface of said substrate, said external contacts being electrically connected to said integrated circuit devices;
conductive structures in said edge regions; and
an underfill material on said external surface of said integrated circuit chip, said underfill material contacting said edge regions and said external contacts,
said underfill material comprising electrically attracted filler particles that affect a coefficient of thermal expansion of said underfill material, and
a density of said filler particles within said underfill material being higher in areas around said edge regions and said external contacts, relative to other regions of said underfill material.

17. The integrated circuit chip according to claim 16, said density of said filler particles making said coefficient of thermal expansion of said underfill material uniform in said areas around said edge regions and said external contacts, relative to said other regions of said underfill material.

18. The integrated circuit chip according to claim 16, said filler particles affecting an elastic modulus of said underfill material.

19. The integrated circuit chip according to claim 16, further comprising a laminated structure attached to said external surface of said integrated circuit chip by said underfill material.

20. The integrated circuit chip according to claim 16, said underfill material comprising a bonding agent.
